(19) United States
(12) Patent Application Publication
(10) Pub. No.: US 2026/0085396 A1
(43) Pub. Date: Mar. 26, 2026

(54) METHOD OF MANUFACTURING MASK ASSEMBLY

(71) Applicant: Samsung Display Co., Ltd., Yongin-si (KR)

(72) Inventor: HOJUN LEE, Yongin-si (KR)

(73) Assignee: Samsung Display Co., Ltd., Yongin-si (KR)

(21) Appl. No.: 19/255,325

(22) Filed: Jun. 30, 2025

(30) Foreign Application Priority Data
Sep. 25, 2024 (KR) 10-2024-0129725

(51) Int. Cl. C23C 14/04; H10K 59/12; H10K 71/16

(52) U.S. Cl. CPC C23C 14/042; H10K 59/1201; H10K 71/166

(57) ABSTRACT

A mask assembly manufacturing method includes providing a wafer, forming a photoresist layer on the wafer, placing a photomask above the photoresist layer and irradiating a light to the photoresist layer through the photomask to form photoresist openings penetrating through upper and lower surfaces of the photoresist layer, forming a mask pattern including silicon (Si) in the photoresist openings using a chemical vapor deposition process, and removing the photoresist layer.

### CROSS-REFERENCE TO RELATED APPLICATION(S)

This application claims priority to and benefits under 35 U.S.C. § 119 of Korean Patent Application No. 10-2024-0129725, filed on Sep. 25, 2024 in the Korean Intellectual Property Office, the entire contents of which are incorporated herein by reference.

### BACKGROUND

### 1. Technical Field

The disclosure relates to a method of manufacturing a mask assembly used in a deposition process.

### 2. Description of the Related Art

A display device includes pixels, and each pixel includes a driving element such as a transistor and a display element such as an organic light emitting diode.

The display element may be formed by stacking an electrode and a light emitting pattern on a substrate.

A process of using a mask assembly through which deposition openings are formed may be performed to form the light emitting pattern. The light emitting pattern may be formed corresponding to an area of the substrate, which is exposed through the deposition openings of the mask assembly. The light emitting pattern may be formed on a target substrate in accordance with the shape and location of the deposition openings of the mask assembly.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The technical objectives to be achieved by the disclosure are not limited to those described herein, and other technical objectives that are not mentioned herein would be clearly understood by a person skilled in the art from the description of the disclosure.

The disclosure provides a method of manufacturing a mask assembly to allow side surfaces of a mask pattern, which define deposition openings of the mask assembly, to have a selected angle.

The disclosure provides a method of manufacturing a mask assembly, which may be capable of preventing the occurrence of a shadow area where a deposition material is not uniformly formed during a process of depositing a deposition material on a target substrate.

Embodiments of the invention provide a method of manufacturing a mask assembly. The method includes providing a wafer, forming a photoresist layer on the wafer, placing a photomask above the photoresist layer and irradiating a light to the photoresist layer through the photomask to form photoresist openings penetrating through upper and lower surfaces of the photoresist layer, forming a mask pattern including silicon (Si) in the photoresist openings using a chemical vapor deposition process, and removing the photoresist layer.

The wafer includes silicon (Si), and the mask pattern includes silicon nitride (SiOₓ) or silicon oxide (SiOₓ).

An upper surface of the wafer and each of side surfaces of the mask pattern form an angle greater than or equal to about 60° and smaller than or equal to about 70° in a cross-sectional view.

The lower surfaces of the photoresist layer and each of side surfaces of the photoresist layer, which define the photoresist openings, form an angle greater than or equal to about 110° and smaller than or equal to about 120° in a cross-sectional view.

After the forming of the mask pattern and before the removing of the photoresist layer, each of portions of the mask pattern may be spaced apart from each other by at least a portion of the photoresist layer, and each of the portions of the mask patterns may have a width that increases as a distance from the wafer increases in a cross-sectional view.

After the forming of the mask pattern and before the removing of the photoresist layer, each of portions of the mask pattern may be spaced apart from each other by at least a portion of the photoresist layer, and each of the portions of the mask pattern has an inverted tapered shape in a cross-sectional view.

After the forming of the mask pattern and before the removing of the photoresist layer, each of portions of the photoresist layer may be spaced apart from each other by a corresponding portion of the mask pattern, each of the portions of the photoresist layer has a width that decreases as a distance from the wafer increases in a cross-sectional view.

The photoresist layer may include a positive photoresist.

Photo openings may be defined through upper and lower surfaces of the photomask, and the photoresist openings formed through the photoresist layer may correspond to the photo openings.

The removing of the photoresist layer may include wet-etching the photoresist layer or ashing the photoresist layer.

Areas where portions of the photoresist layer are arranged in the mask pattern may be defined as pattern areas.

The chemical vapor deposition process may be performed at a temperature of about 60° C. or greater and about 100° C. or less.

The method further may include etching the wafer from a lower surface of the wafer to an upper surface of the wafer to form a cell opening completely penetrating through the lower and upper surfaces of the wafer after the removing of the photoresist layer.

Embodiments of the invention provide a method of manufacturing a mask assembly. The method includes providing a wafer, forming a photoresist layer on the wafer, forming photoresist openings through the photoresist layer and that penetrate through upper and lower surfaces of the photoresist layer and that have an inverted tapered shape in a cross-sectional view, forming a mask pattern based on at least partially filling the photoresist openings, and removing the photoresist layer.

The wafer includes silicon (Si), and the mask pattern includes silicon nitride (SiOₓ) or silicon oxide (SiOₓ).

An upper surface of the wafer and each of side surfaces of the mask pattern form an angle greater than or equal to about 60° and smaller than or equal to about 70° in a cross-sectional view.

After the forming of the mask pattern and before the removing of the photoresist layer, each of portions of the mask pattern may be spaced apart from each other by at least a portion of the photoresist layer, and each of the portions of the mask pattern may have a width that increases as a distance from the wafer increases in a cross-sectional view.

The forming of the photoresist openings may include placing a photomask comprising photo openings defining the photoresist openings, and irradiating a light to the photoresist layer through the photomask, the photoresist layer may include a positive photoresist.

After the forming of the mask pattern and before the removing of the photoresist layer, the photoresist layer and the mask pattern may be directly in contact with an upper surface of the wafer.

The removing of the photoresist layer may include wet-etching the photoresist layer or ashing the photoresist layer.

The method may further include etching the wafer from a lower surface of the wafer to an upper surface of the wafer to form a cell opening, areas where portions of the photoresist layer are arranged in the mask pattern may be defined as pattern areas, deposition openings overlapping the pattern areas and penetrating through upper and lower surfaces of the mask pattern are formed using the mask pattern based on the removing of the photoresist layer, and the cell opening may overlap the photoresist openings.

According to the method of manufacturing the mask assembly of the disclosure, the mask assembly may reduce the occurrence of a shadow area where the deposition material is formed with uneven thickness.

According to the method of manufacturing the mask of the disclosure, the manufacturing process also may be simplified and the cost and time required for the process may be reduced.

In case that the mask assembly manufactured according to the method of manufacturing the mask assembly of the disclosure is used, the yield and reliability of the deposition process may be improved. The resolution, brightness, and lifespan of a display device manufactured through the deposition process also may be enhanced.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view illustrating an electronic device according to an embodiment of the disclosure;

FIG. 2 is a view illustrating use of an electronic device according to an embodiment of the disclosure;

FIG. 3 is an exploded perspective view illustrating an electronic device according to an embodiment of the disclosure;

FIG. 4 is a cross-sectional view illustrating a deposition apparatus according to an embodiment of the disclosure;

FIG. 5 is a plan view illustrating a mask assembly according to an embodiment of the disclosure;

FIG. 6 is an enlarged plan view illustrating an area AA′ of FIG. 5;

FIG. 7 is an enlarged perspective view illustrating a deposition opening of FIG. 6;

FIG. 8 is a flowchart illustrating a method of manufacturing a mask assembly according to an embodiment of the disclosure;

FIG. 9 is a flowchart illustrating a method of manufacturing a mask assembly according to an embodiment of the disclosure;

FIG. 10 is a flowchart illustrating a method of manufacturing a mask assembly according to an embodiment of the disclosure;

FIGS. 11 to 18 are cross-sectional views illustrating processes of a method of manufacturing a mask assembly according to an embodiment of the disclosure;

FIG. 19 is a view illustrating a process of a deposition process using a mask assembly according to a comparative example;

FIG. 20 is a view illustrating a process of a deposition process using a mask assembly according to an embodiment of the disclosure;

FIGS. 21 and 22 are views illustrating a portion of a mask manufactured by a method of manufacturing a mask assembly according to an embodiment of the disclosure;

FIG. 23 is a plan view illustrating a display panel manufactured using a mask assembly shown in FIG. 5;

FIG. 24 is a cross-sectional view illustrating one pixel shown in FIG. 23; and

FIG. 25 is a view illustrating a deposition process performed by the deposition apparatus shown in FIG. 4.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

The disclosure may be variously modified and realized in many different forms, and thus specific embodiments will be illustrated in the drawings and described in detail hereinbelow. However, the disclosure should not be limited to the specific disclosed forms, rather the disclosure should be construed to include all modifications, equivalents, or replacements included in the scope of the disclosure.

In the drawings, sizes, thicknesses, ratios, and dimensions of the elements may be exaggerated for ease of description and for clarity. Like numbers and/or reference characters refer to like elements throughout. In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

The terms “overlap”, “overlapping”, or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

As used herein, the singular forms, “a”, “an” and “the” are intended to include the plural forms as well, unless the context clearly indicates otherwise.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “face” and “facing” mean that a first element may directly or indirectly oppose a second element. In case that a third element intervenes between the first and second element, the first and second element may be understood as being indirectly opposed to one another, although still facing each other.

When an element is described as “not overlapping” or “to not overlap” another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the object from the top, and the phrase “in a cross-sectional view” means viewing a cross-section of which the object is vertically cut from the side. Hence, the expression “in a plan view” used herein may mean that an object is viewed in a third direction (e.g., the z-axis direction or DR3) from the top. The phrase “in a cross-sectional view” means viewing a cross-section in a first direction (e.g., the x-axis direction or DR1) or a second direction (e.g., the y-axis direction or DR2) of which the object is vertically cut from the side. The third direction (e.g., the z-axis direction or DR3) also may be referred to as the “thickness direction”.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

It will be understood that when an element (or a region, a layer, a portion, or the like) is referred to as “being on”, “disposed on”, “connected to” or “coupled to” another element in the specification, it can be directly disposed on, connected or coupled to another element mentioned above, or intervening elements may be disposed therebetween. It will be understood that the terms “connected to” or “coupled to” may include a physical or electrical connection or coupling.

Unless otherwise defined or implied herein, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described with reference to accompanying drawings.

In case that an element is referred to as being “in contact” or “contacted” or the like to another element, the element may be in “electrical contact” or in “physical contact” with another element; or in “indirect contact” or in “direct contact” with another element.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

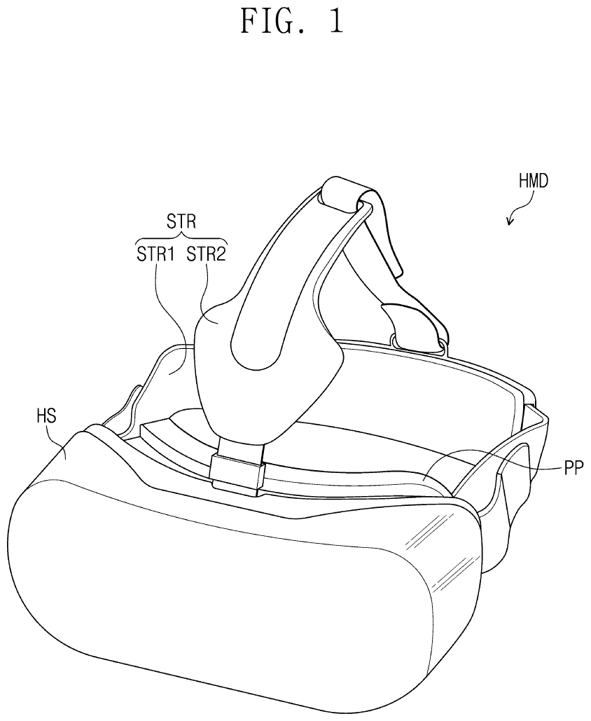

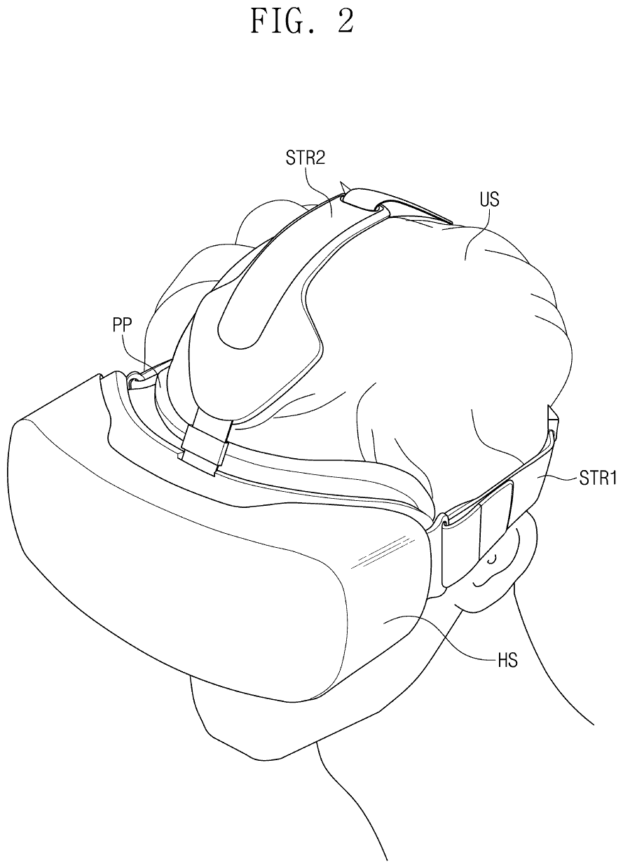

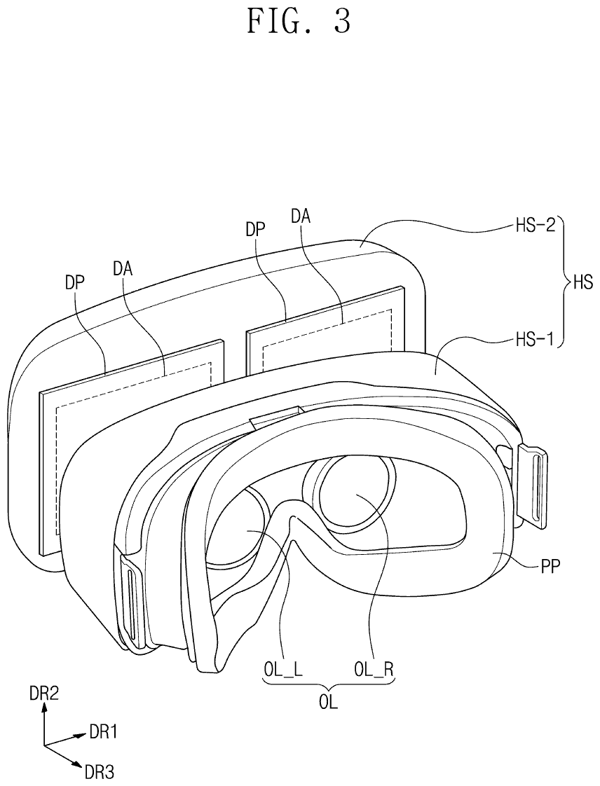

FIG. 1 is a perspective view illustrating an electronic device according to an embodiment of the disclosure. FIG. 2 is a view illustrating the electronic device in use according to an embodiment of the disclosure. FIG. 3 is an exploded perspective view illustrating the electronic device according to an embodiment of the disclosure.

Referring to FIGS. 1 to 3, the electronic device HMD may be activated in response to electrical signals. The electronic device HMD may be a mobile phone, a foldable mobile phone, a notebook computer, a television set, a tablet computer, a car navigation unit, a game unit, or a wearable unit. The wearable unit may be an electronic device that is worn on the body of a user and may include a head-mounted display (HMD) that enables an extended reality (XR).

In a plan view of the specification and/or drawings, “left”, “right”, “up”, and “down” refer to the orientation of the electronic device HMD when viewed in a vertical direction of the electronic device HMD. For example, “left” refers to the negative first direction DR1 (e.g., the negative x-axis direction), “right” refers to the positive first direction DR1 (e.g., the x-axis direction), “up” refers to the positive second direction DR2 (e.g., the y-axis direction), and “down” refers to the negative second direction DR2 (e.g., the negative y-axis direction).

FIG. 1 shows the head-mounted display as a representative example of the electronic device HMD. In the embodiment, the head-mounted display HMD may be an electronic device that is worn on the head of the user. The electronic device HMD may provide images while at least partially blocking a user's view of actual surroundings. As illustrated in FIG. 2, the user US wearing the electronic device HMD may more readily immerse themselves in virtual reality.

The electronic device HMD may include a body part HS, a strap part STR, a cushion part PP, and a display panel (DP of FIG. 3), or a combination thereof. Although not shown in figures, the electronic device HMD may include a variety of sensors and a camera.

The body part HS may be worn on the head of the user US. The body part HS may accommodate the display panel DP displaying the images and an acceleration sensor (not shown) therein. The acceleration sensor may detect the movement of the user US and may transmit a signal to the display panel DP. Accordingly, the display panel DP may provide the images in response to changes in the gaze of the user US. Therefore, the user US may experience a virtual reality that closely resembles real life.

The body part HS may accommodate components with various functions in addition to the above-described components. The body part HS may be referred to as a housing or a case. For instance, a control part (not shown) may be placed on the outside of the body part HS to adjust settings such as volume or screen brightness. The control part may be provided as a physical button or a touch sensor. The body part HS also may accommodate a proximity sensor (not shown) to determine whether the user US wears the electronic device HMD. The body part HS may further include an external display panel.

FIG. 3 illustrates that the body part HS may include a body portion HS-1 and a cover portion HS-2. FIG. 3 illustrates a structure in which the body portion HS-1 is separated from the cover portion HS-2 as a representative example, however, the disclosure should not be limited thereto. For instance, the body portion HS-1 and the cover portion HS-2 may be integral with each other, and the body portion HS-1 and the cover portion HS-2 may not be separated from each other.

The display panels DP may be disposed between the body portion HS-1 and the cover portion HS-2. Each of the display panels DP may display the images through a display area DA. In FIG. 3, an example is provided where a left-eye image and a right-eye image may be respectively provided by the display panels DP separated from each other. As an example, the left-eye image and the right-eye image may be displayed through one display panel. The display panels DP may be driven by separate drivers, however, the disclosure should not be limited thereto. According to an embodiment, the display panels DP may be driven by a single driver.

The display panels DP may generate the images corresponding to image data input thereinto. Each of the display panels DP may be an organic light emitting display panel, an inorganic light emitting display panel, an organic-inorganic light emitting display panel, a quantum dot display panel, a micro-LED display panel, a nano-LED display panel, or a liquid crystal display panel, or a combination thereof. In the embodiment, the organic light emitting display panel will be described as the display panels DP, but the disclosure should not be limited to the organic light emitting display panel.

The strap part STR may be extended to the body part HS to allow the body part HS to be more readily worn on the user US. The strap part STR may include a main strap STR1 and an upper strap STR2.

The main strap STR1 may be worn around the circumference of the head of the user US. The main strap STR1 may fix the body part HS to the user US so that the body part HS may be tightly fit to the head of the user US. The upper strap STR2 may connect the body part HS to the main strap STR1 along an upper portion of the head of the user US. The upper strap STR2 may prevent the body part HS from slipping down. The upper strap STR2 also may enhance the wearing comfort of the user US by distributing a load of the body part HS.

FIG. 1 illustrates a structure in which a length of the main strap STR1 and a length of the upper strap STR2 are adjustable as a representative example, however, the disclosure should not be limited thereto. For instance, according to an embodiment, the main strap STR1 and the upper strap STR2 may have elasticity, and thus, length-adjustable portions of the main strap STR1 and the upper strap STR2 may be omitted.

The strap part STR may be modified into various shapes other than the shape disclosed in FIGS. 1 and 2 as long as the strap part STR allows the body part HS to be secured to the user US. As an example, according to an embodiment, the upper strap STR2 may be omitted. According to an embodiment, the strap part STR also may be modified into various shapes, such as a helmet extended to the body part HS or glasses legs extended to the body part HS.

The cushion part PP may be disposed between the body part HS and the head of the user US. The cushion part PP may be formed of a material that is more readily deformed into different shapes. For instance, the cushion part PP may include a polymer resin (for example, polyurethane, polycarbonate, polypropylene, and polyethylene, or a combination thereof) or a sponge molded by foaming rubber latex, a urethane-based material, or an acrylic-based materials, or a combination thereof, however, the disclosure should not be limited thereto.

The cushion part PP may allow the body part HS to fit securely to the user US, and thus, the wearing comfort of the user US may be enhanced. The cushion part PP may be detachable from the body part HS. According to an embodiment, the cushion part PP may be omitted.

An optical system OL may be disposed in the body portion HS-1 of the body part HS. The optical system OL may enlarge the images provided from the display panels DP. Each of the display panels DP may display or emit the images in a third direction DR3 through the display area DA parallel to a first direction DR1 and a second direction DR2 intersecting the first direction DR1. The optical system OL may be spaced apart from the display panels DP in the third direction DR3. The optical system OL may be placed between the display panels DP and the eyes of the user US in a third direction DR3. The optical system OL may include a right-eye optical system OL_R and a left-eye optical system OL_L. The left-eye optical system OL_L may provide an enlarged image to a left pupil of the user US, and the right-eye optical system OL_R may provide an enlarged image to a right pupil of the user US.

The left-eye optical system OL_L and the right-eye optical system OL_R may be spaced apart from each other in the first direction DR1. A distance between the right-eye optical system OL_R and the left-eye optical system OL_L may be adjusted to correspond to a distance between two eyes of the user US. A distance between the optical system OL and the display panels DP also may be adjusted depending on the eyesight of the user US.

The optical system OL may be a convex aspherical lens. As an example, the optical system OL may be a pancake lens, but it should not be limited thereto. In the embodiment, each of the left-eye optical system OL_L and the right-eye optical system OL_R may include one lens, however, the disclosure should not be limited thereto. For instance, each of the left-eye optical system OL_L and the right-eye optical system OL_R may include a plurality of lenses.

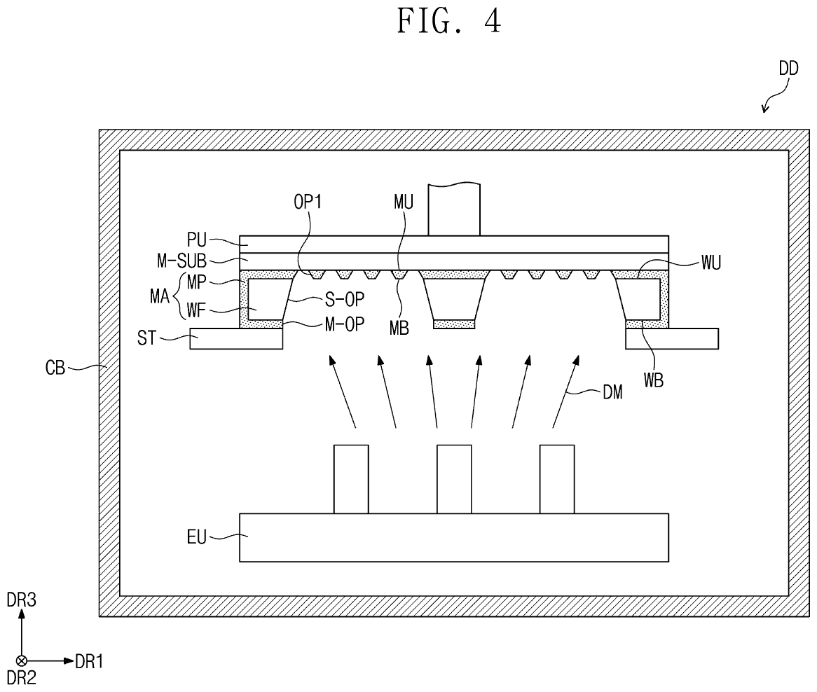

In the embodiment, since the display panels DP may be located very close to the eyes of the user US, the display panels DP may be required to have high resolution compared to conventional display panels. According to a method of manufacturing a mask assembly of the disclosure, the mask assembly MA (refer to FIG. 4) may include a structure that maintains deposition reliability even during a manufacturing process of the high-resolution display panel (refer to FIG. 4). Hereinafter, structural characteristics of the mask assembly MA (refer to FIG. 4) and each process of the mask assembly manufacturing method will be described with reference to the drawings.

FIG. 4 is a cross-sectional view illustrating a deposition apparatus DD according to an embodiment of the disclosure.

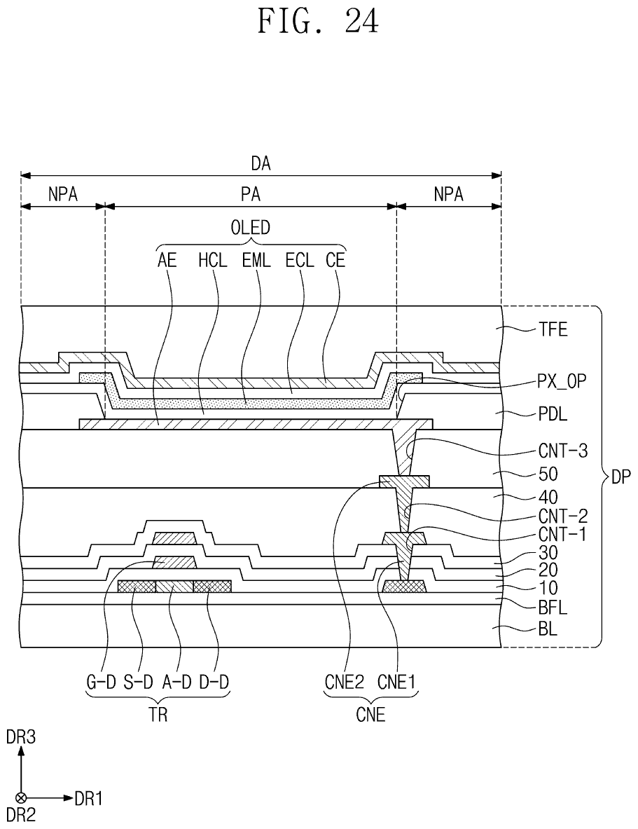

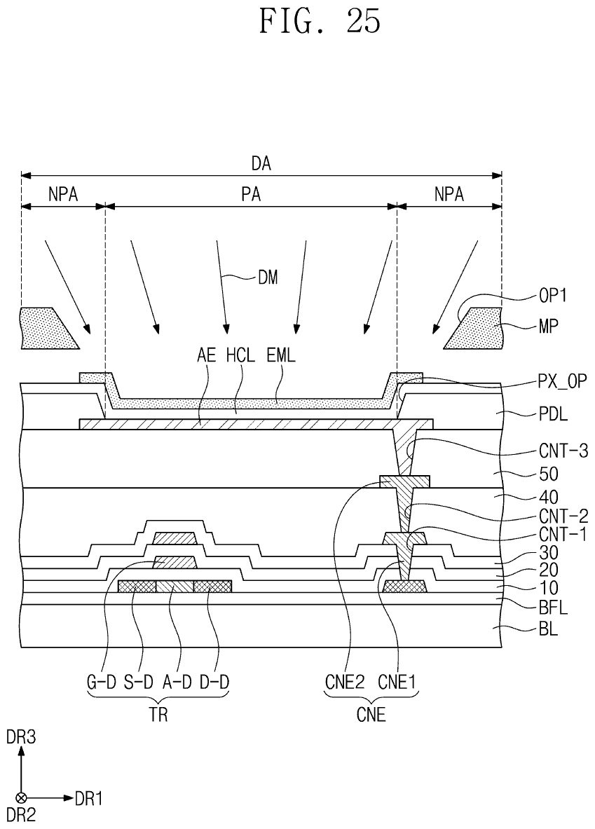

The deposition apparatus DD according to the disclosure may be used to form one or more of functional layers included in a display panel DP (refer to FIG. 24) described below. As an example, the deposition apparatus DD may be used to perform a deposition process for a light emitting layer EML (refer to FIG. 24) of the display panel DP (refer to FIG. 24).

Referring to FIG. 4, the deposition apparatus DD may include a chamber CB, a fixing unit PU, a deposition unit EU, the mask assembly MA, and a stage ST, or a combination thereof. The deposition apparatus DD may further include additional mechanical apparatuses to implement an inline system.

The chamber CB may include a bottom surface, a ceiling surface, and sidewalls connecting the bottom surface and the ceiling surface to provide an inner space in the chamber CB. The bottom surface of the chamber CB may be substantially parallel to a plane defined by the first direction DR1 and the second direction DR2, and a normal line direction of the bottom surface of the chamber CB may be substantially parallel to the third direction DR3.

The fixing unit PU, the deposition unit EU, the mask assembly MA, and the stage ST may be placed in the inner space of the chamber CB. A target substrate M-SUB also may be placed in the inner space of the chamber CB.

The chamber CB may provide an enclosed space therein. Accordingly, the chamber CB may set a deposition condition inside the chamber CB to a vacuum state.

Although not shown in figures, the chamber CB may include one or more gates. The chamber CB may be opened or closed by the gate. The mask assembly MA and the target substrate M-SUB may enter and exit through the gate provided in the chamber CB.

The fixing unit PU may be placed above the deposition unit EU in the chamber CB. The fixing unit PU may function to attach the mask assembly MA to the target substrate M-SUB. FIG. 4 illustrates a structure in which the mask assembly MA is in contact with the target substrate M-SUB as a representative example. However, the disclosure should not be limited thereto, and the mask assembly MA may be spaced apart from the target substrate M-SUB in the third direction DR3 by a gap without being in contact with the target substrate M-SUB.

The fixing unit PU may include a magnetic material to secure the mask assembly MA to the target substrate M-SUB. According to an embodiment, the fixing unit PU may include an electro-static chuck. The fixing unit PU may apply an attractive force to the mask assembly MA to prevent the mask assembly MA from sagging due to gravity.

Although not shown in figures, the fixing unit PU may further include a holding part to hold the target substrate M-SUB. The holding part may keep the target substrate M-SUB stationary during the deposition process. As an example, the holding part may be defined as a groove to which the target substrate M-SUB may be detachably coupled.

The target substrate M-SUB may be a processing target on which a deposition material DM is deposited. As an example, the target substrate M-SUB may include a support substrate and a synthetic resin layer disposed on the support substrate and corresponding to a base substrate BL (refer to FIG. 24). The support substrate may be removed in the latter stages of the manufacturing process of the display panel DP (refer to FIG. 24). Depending on the component formed through the deposition process, the target substrate M-SUB may include some components of the display panel DP (refer to FIG. 24) formed on the base substrate BL (refer to FIG. 24).

The deposition unit EU may be placed in the chamber CB to face the fixing unit PU. The deposition unit EU may include a space that contains the deposition material DM and one or more nozzles that spray the deposition material DM. FIG. 4 illustrates three nozzles of the deposition unit EU as a representative example, however, the disclosure should not be limited thereto.

The deposition material DM may include an inorganic material, a metal material, or an organic material that is able to sublimate or vaporize. The deposition material DM may be deposited on the target substrate M-SUB in a pattern through the mask assembly MA.

The mask assembly MA may be disposed on the stage ST. The mask assembly MA may be disposed between the deposition unit EU and the target substrate M-SUB. As an example, the mask assembly MA may be fixed to the stage ST and may be attached to and detached from the stage ST. An upper surface of the mask assembly MA may face the target substrate M-SUB.

The mask assembly MA may allow the deposition material DM to be deposited on the target substrate M-SUB in the pattern. The mask assembly MA may allow the deposition material (DM) to selectively pass through specific areas.

The mask assembly MA may include a wafer WF and a mask pattern MP.

The mask pattern MP may surround at least a portion of the wafer WF. As an example, the mask pattern MP may surround an upper surface WU and a lower surface WB of the wafer WF. However, in case that the mask pattern MP surrounds the lower surface WB of the wafer WF, the mask pattern MP may include a mask opening M-OP overlapping a cell opening S-OP described below.

The mask pattern MP may include a deposition opening OP1. The deposition opening OP1 may be defined through an upper surface MU and a lower surface MB of the mask pattern MP. The deposition material DM may pass through the deposition opening OP1 and may be blocked in other areas.

The mask pattern MP may include a silicon-based inorganic material. As an example, the mask pattern MP may include one of silicon oxide (SiOₓ) and silicon nitride (SiNₓ), or a combination thereof.

The wafer WF may include silicon (Si). The cell opening S-OP may be defined through an upper surface WU and a lower surface WB of the wafer WF.

The deposition openings OP1 may overlap the cell opening S-OP in a plan view. The cell openings S-OP may define an area in which a deposition pattern may be formed on the target substrate M-SUB.

The deposition material DM may be formed on a deposition surface of the target substrate M-SUB in a pattern (e.g., a selectable pattern) corresponding to the deposition opening OP1 after passing through the mask opening M-OP, the cell opening S-OP, and the deposition opening OP1. The deposition material DM may pass through the mask opening M-OP, the cell opening S-OP, and the deposition opening OP1 and may be formed as a pattern on a deposition surface of the target substrate M-SUB to correspond to the deposition opening OP1.

The stage ST may be disposed between the deposition unit EU and the fixing unit PU. The stage ST may be positioned outside the movement path of the deposition material DM supplied from the deposition unit EU to the target substrate M-SUB.

The stage ST may support the mask assembly MA. The stage ST may provide a seating surface on which the mask assembly MA is disposed. The seating surface may be substantially parallel to the first direction DR1 and the second direction DR2. The seating surface of the stage ST may be substantially parallel to the bottom of the chamber CB.

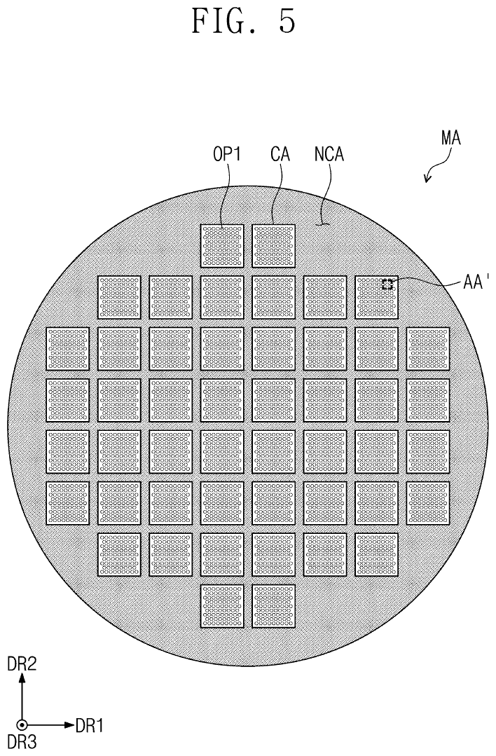

FIG. 5 is a plan view illustrating the mask assembly MA according to an embodiment of the disclosure.

Referring to FIG. 5, the mask assembly MA may have a circular shape in a plan view, however, the disclosure should not be limited thereto. As an example, the mask assembly MA may have a polygonal shape.

The mask assembly MA may include cell areas CA and a peripheral area NCA surrounding the cell areas CA in a plan view.

The cell areas CA may correspond to the cell openings S-OP (refer to FIG. 4). FIG. 5 illustrates forty-eight cell areas CA arranged in the first direction DR1 and the second direction DR2 as a representative example, but the disclosure should not be limited thereto. The arrangement and number of the cell areas CA may be different from those illustrated in FIG. 5.

The deposition openings OP1 may be defined in the cell area CA in a plan view. The deposition openings OP1 may be arranged in each of the cell areas CA and may be spaced apart from each other in the first direction DR1 and the second direction DR2 in each of the cell areas CA. FIG. 5 illustrates the deposition openings OP1 arranged in the first direction DR1 and the second direction DR2 as a representative example. However, the disclosure should not be limited thereto, and according to an embodiment, the deposition openings OP1 may be defined to correspond to locations of patterns formed in the target substrate M-SUB.

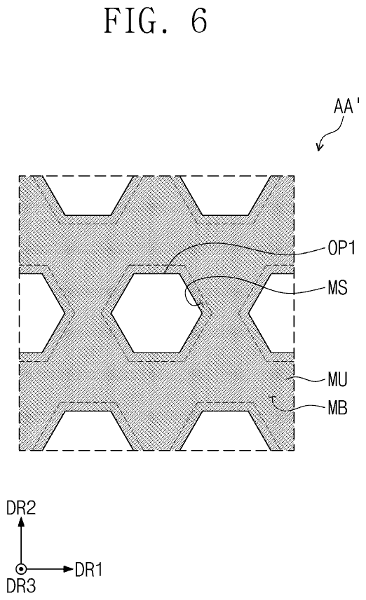

FIG. 6 is an enlarged plan view illustrating an area AA′ of FIG. 5. FIG. 7 is an enlarged perspective view illustrating a deposition opening OP1 of FIG. 6.

Hereinafter, the shape-related features of the deposition opening OP1 will be described with reference to FIGS. 6 and 7.

The deposition opening OP1 may have a shape penetrating through the upper surface MU and the lower surface MB of the mask pattern MP and may be defined by a side surface MS of the mask pattern MP.

FIG. 6 illustrates the shape of the deposition opening OP1 in a plan view. For the sake of explanation, the shape of the deposition opening OP1 in a plan view above the upper surface MU of the mask pattern MP is represented by a solid line, and the shape of the deposition opening OP1 in a plan view below the lower surface MB of the mask pattern MP is represented by a dotted line.

According to the embodiment, the deposition opening OP1 defined through the mask pattern MP may have a hexagonal shape in the upper surface MU and the lower surface MB of the mask pattern MP, however, the disclosure should not be limited thereto. According to an embodiment, the shape of the deposition opening OP1 in a plan view may correspond to the shape of the deposition pattern to be formed on the target substrate M-SUB.

The shape of the deposition opening OP1 defined in the lower surface MB of the mask pattern MP may be greater than the shape of the deposition opening OP1 defined in the upper surface MU of the mask pattern MP. For example, a size in a plan view of the deposition opening OP1 defined in the lower surface MB of the mask pattern MP may be greater or larger than a size of the deposition opening OP1 defined in the upper surface MU of the mask pattern MP.

The shape in a plan view of the deposition opening OP1 defined in the lower surface MB of the mask pattern MP may surround, from the outside in the first direction DR1 and the second direction DR2, the shape or outer periphery of the deposition opening OP1 defined in the upper surface MU of the mask pattern MP. FIG. 6 illustrates a structure in which the hexagonal shape defined by the deposition opening OP1 and represented by the dotted line surrounds, from the outside in the first direction DR1 and the second direction DR2, the hexagonal shape represented by the solid line.

The shape or outer periphery in a plan view of the deposition opening OP1 defined in the lower surface MB of the mask pattern MP may not overlap the shape or outer periphery of the deposition opening OP1 defined in the upper surface MU of the mask pattern MP. FIG. 6 illustrates a structure in which the outer periphery of the deposition opening OP1 and having a hexagonal shape represented by the dotted line is defined outside the outer periphery of the deposition opening OP1 having a hexagonal shape represented by the solid line and does not overlap in a plan view the outer periphery having a hexagonal shape represented by the solid line.

Referring to FIG. 7, a plane including the lower surface MB of the mask pattern MP and each of the side surfaces MS of the mask pattern MP may form an angle. In the disclosure, the angle may be referred to as an opening angle OA. The opening angle OA may be an acute angle. For example, the opening angle OA may be greater than or equal to about 60° and smaller than or equal to about 70°. Hence, an upper surface (WU of FIG. 4) of the wafer WF (e.g., directly contacting the lower surface MB of the mask pattern MP) and each of the side surfaces MS of the mask pattern MP may form an angle OA that is greater than or equal to about 60° and smaller than or equal to about 70° in a cross-sectional view.

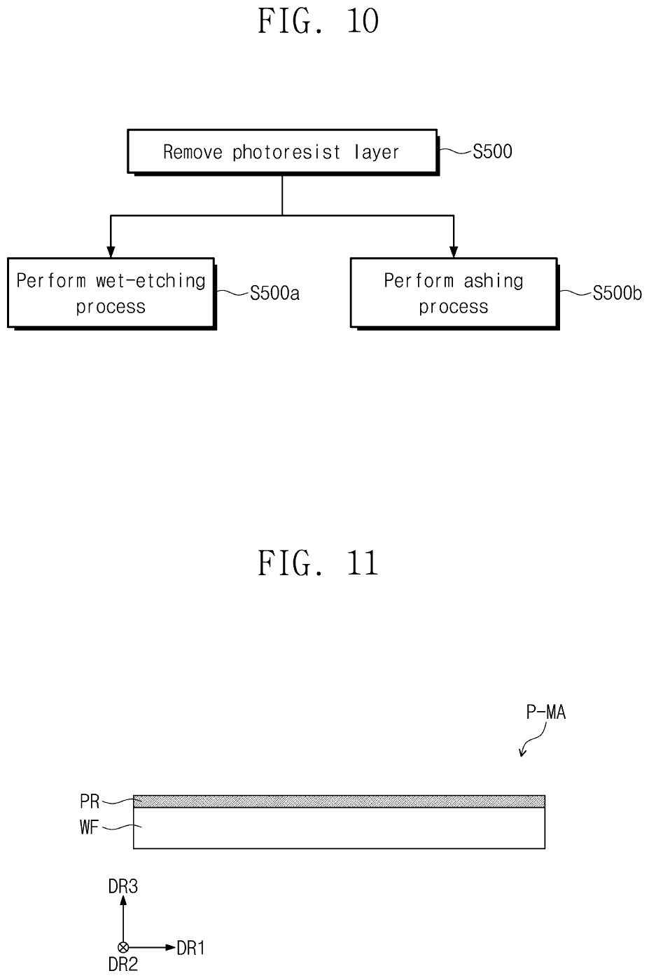

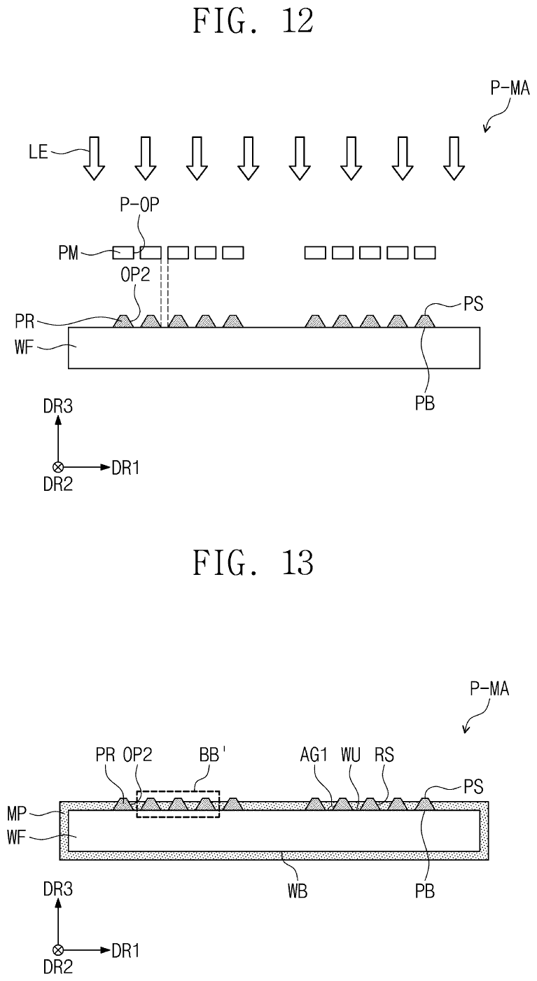

According to the mask assembly manufacturing method, a photoresist layer PR (refer to FIGS. 11 and 12) and a photoresist opening OP2 (refer to FIG. 12) may be formed, and then a chemical vapor deposition process may be performed on the mask pattern MP (refer to FIG. 4). Thus, the mask assembly MA (refer to FIG. 4) may include a deposition opening OP1 having an opening angle OA that is an acute angle greater than or equal to about 60° and smaller than or equal to about 70°.

For example, in contrast to a conventional mask assembly manufacturing method in which a photoresist layer is formed on the deposition material and the deposition material is patterned using the photoresist layer, according to the disclosure, the chemical vapor deposition process may be performed after the photoresist layer PR (refer to FIG. 12) is formed and patterned, and thus, the deposition opening OP1, whose opening angle OA is the acute angle, may be formed.

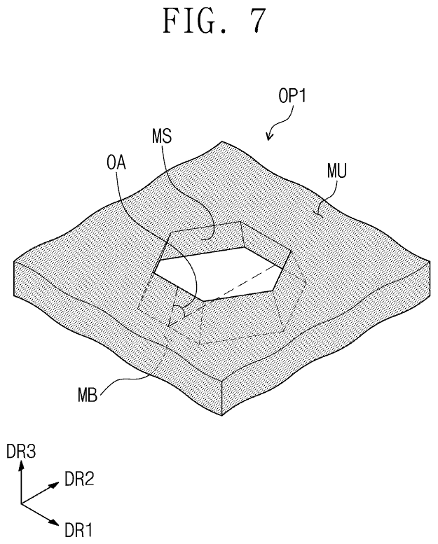

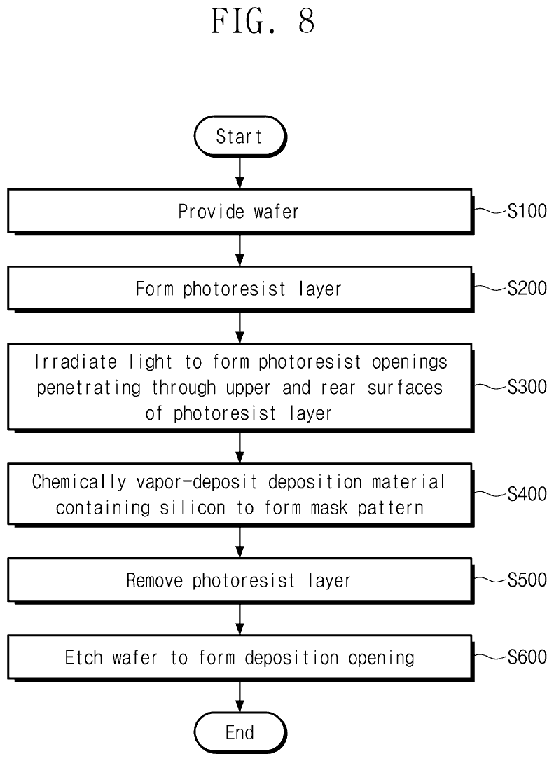

FIG. 8 is a flowchart illustrating the mask assembly manufacturing method according to an embodiment of the disclosure.

Referring to FIG. 8, the mask assembly manufacturing method according to an embodiment of the disclosure may include providing the wafer (S100), forming the photoresist layer on the wafer (S200), placing a photomask above the photoresist layer and irradiating a light through the photomask to the photoresist layer to form the photoresist openings penetrating through upper and lower surfaces of the photoresist layer (S300), and forming the mask pattern including silicon (Si) in the photoresist openings using the chemical vapor deposition (S400).

The mask assembly manufacturing method according to an embodiment of the disclosure may further include removing the photoresist layer (S500) after the forming of the mask pattern (S400).

The mask assembly manufacturing method according to an embodiment of the disclosure may further include etching the wafer in a direction from a lower surface to an upper surface of the wafer to form the cell opening completely penetrating through the lower and upper surface of the wafer and overlapping the deposition opening (S600) after the removing of the photoresist layer (S500).

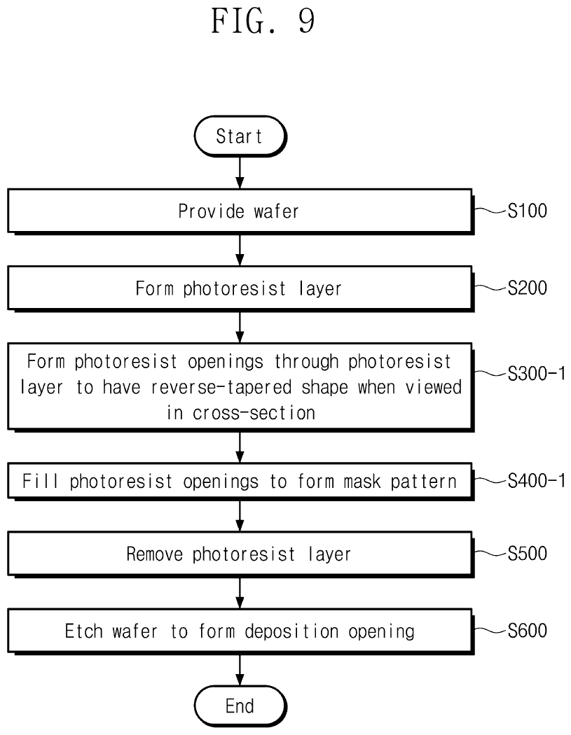

FIG. 9 is a flowchart illustrating the mask assembly manufacturing method according to an embodiment of the disclosure.

The mask assembly manufacturing method according to an embodiment of the disclosure may include providing the wafer (S100), forming the photoresist layer on the wafer (S200), forming the photoresist openings penetrating through upper and lower surfaces of the photoresist layer and having an inverted tapered shape (S300-1), and at least partially filling the photoresist openings to form the mask pattern (S400-1).

The mask assembly manufacturing method according to an embodiment of the disclosure may further include removing the photoresist layer (S500) after the forming of the mask pattern (S400-1).

The mask assembly manufacturing method according to an embodiment of the disclosure may further include etching the wafer in the direction from the lower surface to the upper surface of the wafer to form the cell opening completely penetrating through the lower and upper surfaces of the wafer and overlapping the deposition opening (S600) after the removing of the photoresist layer (S500).

FIG. 10 is a flowchart illustrating the mask assembly manufacturing method according to an embodiment of the disclosure.

Referring to FIG. 10 the removing of the photoresist layer (S500) may include wet-etching the photoresist layer (S500a) or ashing the photoresist layer (S500b). This will be described below with reference to FIG. 15.

FIGS. 11 to 18 are cross-sectional views illustrating processes of the mask assembly manufacturing method according to an embodiment of the disclosure.

Hereinafter, the mask assembly manufacturing method according to an embodiment of the disclosure will be described with reference to FIGS. 11 to 18. Redundant descriptions of the configurations shown in FIGS. 4 to 7 will be omitted, and the descriptions will be focused on the time-series characteristics of the mask assembly manufacturing method.

Hereinafter, for the convenience of explanation, the mask assembly MA in a state before completion in the manufacturing process of the mask assembly MA will be referred to as a preliminary mask P-MA

Referring to FIG. 11, the preliminary mask P-MA may be provided. The preliminary mask P-MA shown in FIG. 11 may include the wafer WF and the photoresist layer PR formed on the wafer WF. The preliminary mask P-MA may be formed through the providing of the wafer (S100, refer to FIG. 8) and the forming of the photoresist layer on the wafer (S200, refer to FIG. 8).

The photoresist layer PR may include a photoresist. For example, the photoresist layer PR may include a positive photoresist. Accordingly, a positive photoresist process or positive photoresitry process may be performed on the photoresist layer PR as described below.

Referring to FIG. 12, a light LE may be irradiated through the photomask PM and onto the photoresist layer PR to form photoresist openings OP2 penetrating completely through an upper surface PS and a lower surface PB of the photoresist layer PR (S300).

The forming of the deposition openings (S300, refer to FIG. 8) may include placing the photomask PM through which photo openings P-OP corresponding to the photoresist openings OP2 are defined above the photoresist layer PR and irradiating the light LE to the photoresist layer PR. Hence, the photoresist openings OP2 formed through the photoresist layer PR correspond to (or overlap) the photo openings P-OP.

In the embodiment, the light LE may include light in an ultraviolet (UV) wavelength range.

In the embodiment, the forming of the deposition opening (S300, refer to FIG. 8) may further include performing a vacuum contact develop (VCD) process to induce uniform contact of a developer on a surface of the photoresist layer and a post-exposure bake (PEB) process. A hot bake (HBK) process to evaporate a solvent in the photoresist prior to the vacuum contact develop (VCD) process may be omitted.

The vacuum contact develop process may be performed under a vacuum pressure of about 25 Pa or greater and about 95 Pa or less. For example, the vacuum contact develop process may be performed under a vacuum pressure of about 60 Pa or greater and about 70 Pa or less. However, the disclosure should not be limited thereto, and the pressure may be adjusted by taking into account the material for the photoresist layer PR and an angle (AG1 of FIG. 13) of the photoresist opening OP2.

The photo openings P-OP may be formed through upper and lower surfaces of the photomask PM. The arrangement and shape of the photo openings P-OP may correspond to the deposition openings OP1 (refer to FIG. 15) formed through the photoresist layer PR.

However, since the photoresist layer PR according to the embodiment of the disclosure may include the positive photoresist, each of the side surfaces RS (refer to FIG. 13) of the photoresist layer PR, which defines the deposition openings OP1, may form an angle with the lower surface PB of the photoresist layer PR in the cross-sectional view, described below.

Referring to FIG. 13, the forming of the mask pattern MP (S400, refer to FIG. 8) may be performed.

The forming of the mask pattern MP may be performed by a chemical vapor deposition (CVD) process that deposits the deposition material onto the wafer WF and at least partially fills the photoresist openings OP2.

The deposition material may include silicon (Si). As an example, the deposition material may include at least one of silicon oxide (SiOₓ) and/or silicon nitride (SiNₓ), or a combination thereof.

FIG. 13 illustrates a structure in which the deposition material is deposited on the upper surface WU, the lower surface WB, and side surfaces of the wafer WF as a representative example.

The deposition material may be filled at least partially in the photoresist openings OP2.

However, the disclosure should not be limited thereto as long as the deposition material is deposited on the upper surface of the wafer WF. As an example, the deposition material may be deposited on the upper surface WU of the wafer WF and may not be deposited on at least a portion of other surfaces.

However, in a case where the chemical vapor deposition process is performed at a high temperature of about 300° C., an outgas may be generated from the photoresist layer PR, and as a result, a surface quality of the mask pattern MP may be deteriorated. Accordingly, the chemical vapor deposition process may be performed at a relatively low temperature in an embodiment of the disclosure. As an example, the chemical vapor deposition process may be performed at a temperature of about 60° C. or greater and about 100° C. or less. For example, the chemical vapor deposition process may be performed at a temperature of about 70° C. or greater and about 90° C. or less.

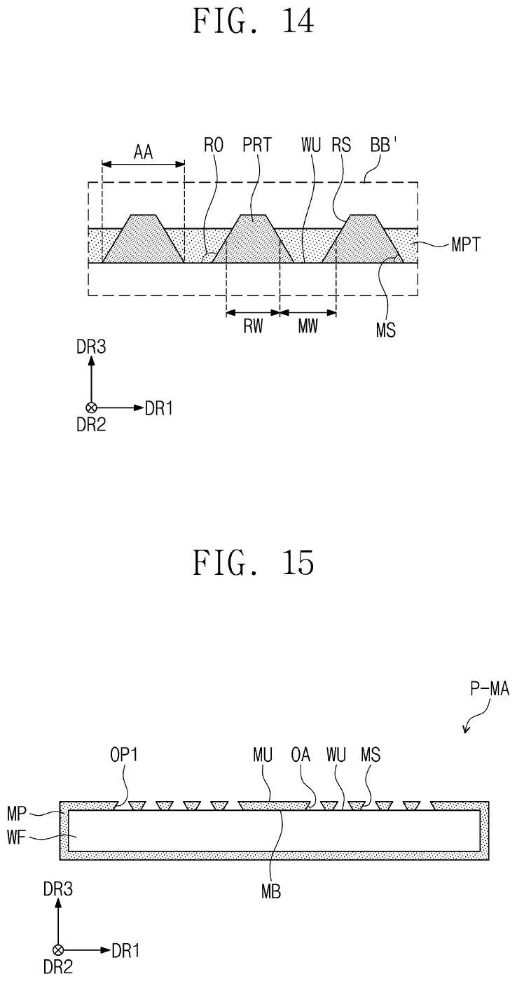

FIG. 14 is an enlarged view of an area BB′ of FIG. 13.

For the convenience of explanation, a trapezoidal-shaped portion of the photoresist layer PR as shown in FIG. 14 is referred to as a portion PRT of the photoresist layer PR, and an inverted trapezoidal-shaped portion of the mask pattern MP as shown in FIG. 14 is referred to as a portion MPT of the mask pattern MP.

Referring to FIG. 14 in a cross-sectional view, each of the portions PRT of the photoresist layer PR, which are spaced apart from each other to allow each of the portions MPT of the mask pattern MP to be disposed between the portions PRT of the photoresist layer PR, may have a width RW decreasing as a distance from the wafer WF increases along the third direction DR3. The width RW of each of the portions PRT of the photoresist layer PR may decrease as the distance from the wafer WF increases along the third direction DR3.

Each of the portions PRT of the photoresist layer PR may have a tapered shape. For example, each of the portions PRT of the photoresist layer PR may have the width RW that increases from top to bottom along the third direction DR3.

The upper surface WU of the wafer WF and each of the side surfaces RS of the photoresist layer PR, which define the photoresist openings OP2, may form an angle. For the sake of explanation, the angle is referred to as a photoresist layer angle RO.

The photoresist layer angle RO may be an obtuse angle. As an example, the photoresist layer angle RO may be about 110° or greater and about 120° or less. Hence, the lower surface (PB of FIG. 13) of the photoresist layer PR (e.g., directly contacting the upper surface WU of the wafer WF) and each of side surfaces RS of the photoresist layer, which define the photoresist openings OP2, may form an angle (AG1 of FIG. 13; RO of FIG. 14) greater than or equal to about 110° and smaller than or equal to about 120° in a cross-sectional view.

The portions PRT of the mask pattern MP may be formed in the photoresist openings OP2. Each of the portions MPT of the mask pattern MP, which is located in the photoresist openings OP2, may have a shape corresponding to the shape of the photoresist opening OP2.

The portions MPT of the mask pattern MP, which are disposed in the photoresist openings OP2 and spaced apart from each other in the first direction DR1 in a cross-sectional view, may be spaced apart from each other such that each of the portions PRT of the photoresist layer PR may be disposed between the portions MPT.

After the forming of the mask pattern (S400) and before the removing of the photoresist layer (S500), each of the portions MPT of the mask pattern MP, which are spaced apart from each other such that the photoresist layer PR is disposed between the portions MPT, may have a width (MW of FIG. 14) that increases as a distance from the wafer WF increases in the cross-sectional view. For example, the width MW of each of the portions MPT of the mask pattern MP may increase along the third direction DR3.

Each of the portions MPT of the mask pattern MP, which may be spaced apart from each other by the photoresist layer PR in a cross-sectional view, may have an inverted tapered shape. For example, each of the portions MPT of the mask pattern MP may have the width MW that decreases from top to bottom of the portions MPT of the mask pattern MP along the third direction DR3.

The shape of each of the portions MPT of the mask pattern may be indirectly determined by the shape of each of the portions PRT of the photoresist layer PR. For example, the shape of each of the portions MPT of the mask pattern may be determined by the shape of the photoresist opening OP2 (refer to FIG. 13) defined by the side surface RS of the photoresist layer PR.

FIG. 14 illustrates the structure in which the width MW of each of the portions MPT of the mask pattern MP linearly increases along the third direction DR3, however, the disclosure should not be limited thereto. As an example, in case that the side surface MS of the portions MPT of the mask pattern MP includes a curved surface, the width MW of the portions MPT of the mask pattern MP may increase non-linearly.

In the disclosure, each area in which the portions PRT of the photoresist layer PR are arranged in the mask pattern MP may be defined as a pattern area AA.

After the forming of the mask pattern (S400) and before the removing of the photoresist layer (S500), the photoresist layer PR and the mask pattern MP may be in contact with the upper surface WU of the wafer WF. The photoresist layer PR and the mask pattern MP may contact (e.g., directly contact) the upper surface WU of the wafer WF.

Referring to FIG. 15, the removing of the photoresist layer may be performed (S500).

In the operation, the photoresist layer PR may be selectively removed without removal of other layers or other elements.

The removing of the photoresist layer (S500) may include the wet-etching of the photoresist layer (S500a, refer to FIG. 10). The wet-etching of the photoresist layer (S500a, refer to FIG. 10) may include dissolving the photoresist layer PR through an acidic or alkaline solution.

According to an embodiment, the removing of the photoresist layer (S500) may include the ashing of the photoresist layer (S500b, refer to FIG. 10). The ashing of the photoresist layer (S500b, refer to FIG. 10) may include irradiating high-temperature plasma to the photoresist layer PR to oxidize the photoresist layer PR.

As illustrated in FIGS. 14 and 15, the deposition openings OP1 may be formed through the upper surface MU and the lower surface MB of the mask pattern MP to overlap the pattern area AA. The deposition openings OP1 overlapping the pattern area AA and penetrating through the upper surface MU and the lower surface MB of the mask pattern MP may be formed based on the removing of the photoresist layer PR.

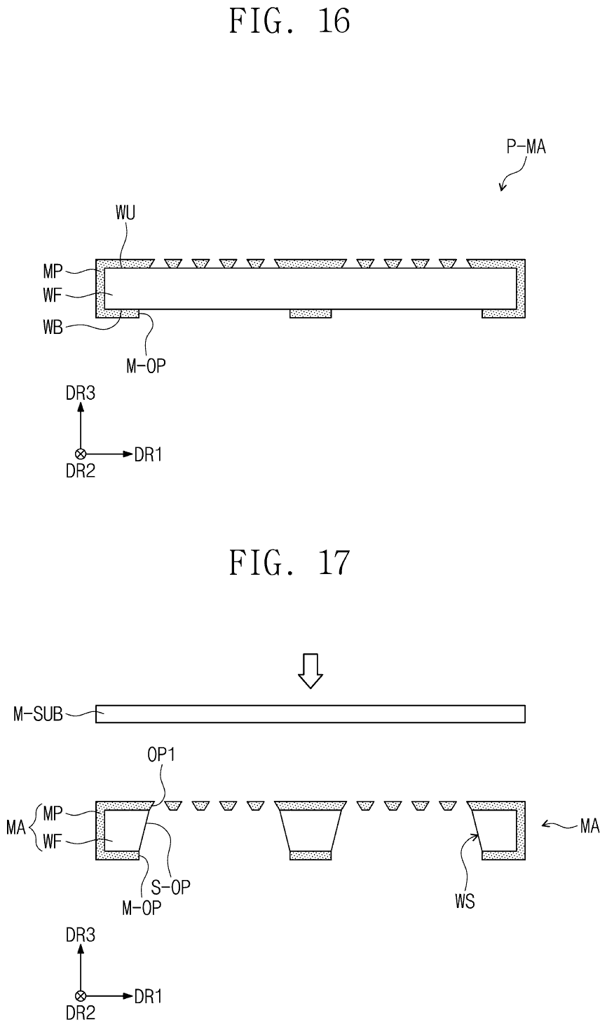

Referring to FIG. 16, the mask opening M-OP may be formed through the mask pattern MP disposed on the lower surface WB of the wafer WF. The mask opening M-OP may have a shape corresponding to a shape of the cell opening S-OP described below. The mask opening M-OP may be formed through a dry-etching process.

Referring to FIG. 17, the etching of the wafer to form the cell opening may be performed (S600, refer to FIG. 8).

The wafer WF may be etched in a third direction DR3 from the lower surface WB to the upper surface WU to form a cell opening S-OP completely penetrating through the lower surface WB and the upper surface WU of the wafer. The wafer WF may be anisotropically etched in the direction from the lower surface WB to the upper surface WU. In the etching process of the wafer WF, an etch rate in the third direction DR3 of the wafer WF may be greater than an etch rate in the first direction DR1 and the second direction DR2 of the wafer WF. Accordingly, the side surface WS of the wafer WF, which defines the cell opening S-OP, may have an inverted tapered shape in a cross-sectional view.

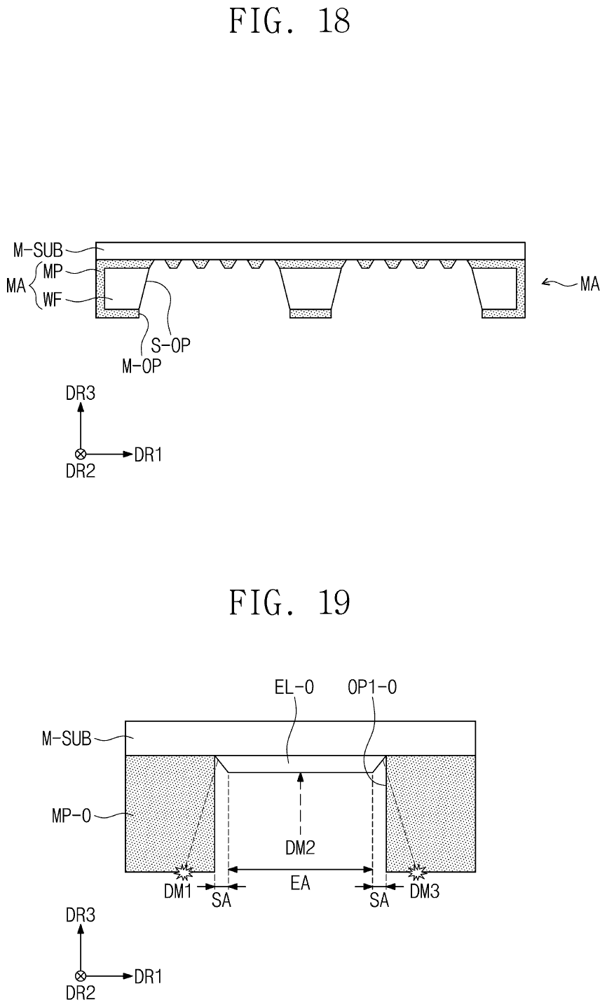

Referring to FIG. 18, the target substrate M-SUB may be disposed on the mask assembly MA. The deposition in the third direction DR3 of the deposition material DM (refer to FIG. 4) onto the target substrate M-SUB may then be performed in the deposition apparatus DD (refer to FIG. 4).

FIG. 19 is a cross-sectional view illustrating a deposition process using a mask assembly according to a comparative example.

FIG. 19 illustrates a deposition process using a conventional mask assembly.

Deposition materials DM1, DM2, and DM3 may be deposited on a lower surface of a target substrate M-SUB through a deposition opening OP1-0. Accordingly, a light emitting layer EL-0 may be formed on the target substrate M-SUB.

In the conventional mask assembly, a side surface of a mask pattern MP-0, which defines the deposition opening OP1-0, is parallel to a third direction DR3.

For the sake of explanation, FIG. 19 illustrates first, second, and third deposition materials DM1, DM2, and DM3 provided to the target substrate M-SUB along different paths from each other.

Referring to FIG. 19, the paths through which the first deposition material DM1 and the third deposition material DM3 are provided to the target substrate M-SUB may be blocked by the mask pattern MP-0. The second deposition material DM2 may be deposited on the lower surface of the target substrate M-SUB after passing through the deposition opening OP1-0.

Accordingly, a normal deposition area EA and a shadow area SA may be formed in the lower surface of the target substrate M-SUB through the deposition process using the conventional mask assembly. The normal deposition area EA corresponds to an area where the deposition materials DM1, DM2, and DM3 may be readily deposited, and the shadow areas SA correspond to areas where some of the paths through which the deposition materials travel may be blocked by the mask pattern MP-0, resulting in reduced deposition of materials DM1, DM2, and DM3.

According to the deposition process using the conventional mask assembly, the light emitting layer EL-0 has a constant thickness in the normal deposition area EA but a smaller thickness in the shadow areas SA. As described above, in case that the thickness of the light emitting layer EL-0 is not constant, the reliability of a display device is deteriorated, and the brightness and color reproduction rate of the display device are deteriorated.

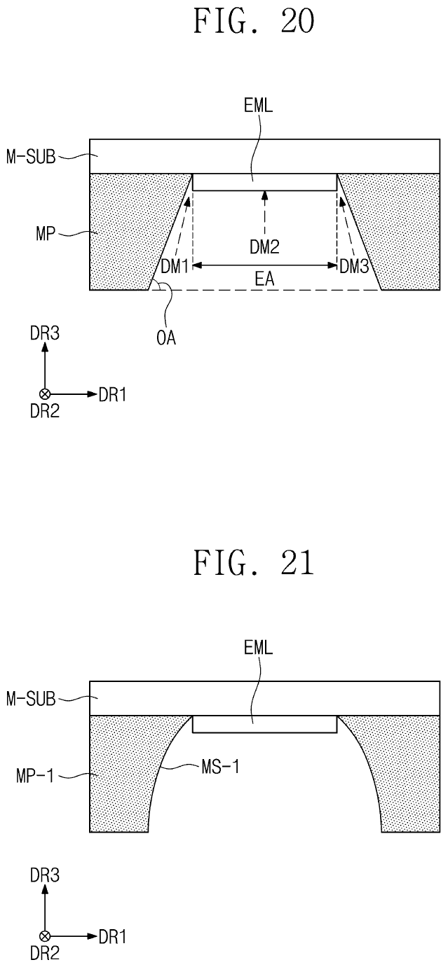

FIG. 20 is a cross-sectional view illustrating a deposition process using a mask assembly according to an embodiment of the disclosure.

Referring to FIG. 20, paths through which deposition materials DM1 and DM3 are provided to the lower surface of the target substrate M-SUB in the third direction DR3 (for example, for formation of a light emitting layer EML) may not be blocked in the deposition process using the mask assembly according to an embodiment of the disclosure. According to the embodiment, since the opening angle OA is the obtuse angle, the possibility that the deposition materials DM1 to DM3 reach the lower surface of the mask pattern MP may significantly increase.

Unlike the conventional conventional mask assembly, use of the mask assembly according to an embodiment may cause first and third deposition materials DM1 and DM3 to also reach the lower surface of the target substrate M-SUB.

According to the deposition process using the mask assembly of the disclosure, the shadow areas SA (refer to FIG. 19) may be removed or largely reduced. A normal deposition area EA also may significantly increase.

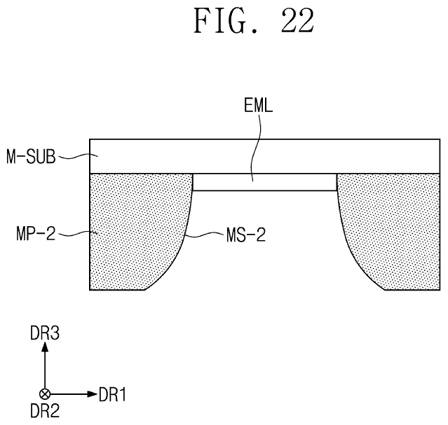

FIGS. 21 and 22 are cross-sectional views illustrating a portion of a mask assembly manufactured by the mask assembly manufacturing method according to an embodiment of the disclosure.

In FIGS. 21 and 22, the same/similar reference numerals denote the same/similar elements in FIGS. 1 to 20, and thus, detailed descriptions of the same/similar elements will be omitted.

According to the disclosure, since the shape of the deposition opening OP1 may be indirectly determined by the shape of the photoresist opening OP2, the side surfaces of the mask pattern MP that define the deposition opening OP1 may be curved by controlling the shape of the photoresist opening OP2.

Referring to FIG. 21, a side surface MS-1 of a mask pattern MP-1 may be concave in a direction toward the target substrate M-SUB according to an embodiment of the disclosure.

Referring to FIG. 22 a side surface MS-2 of a mask pattern MP-2 may be convex in a direction away from the target substrate M-SUB according to an embodiment of the disclosure.

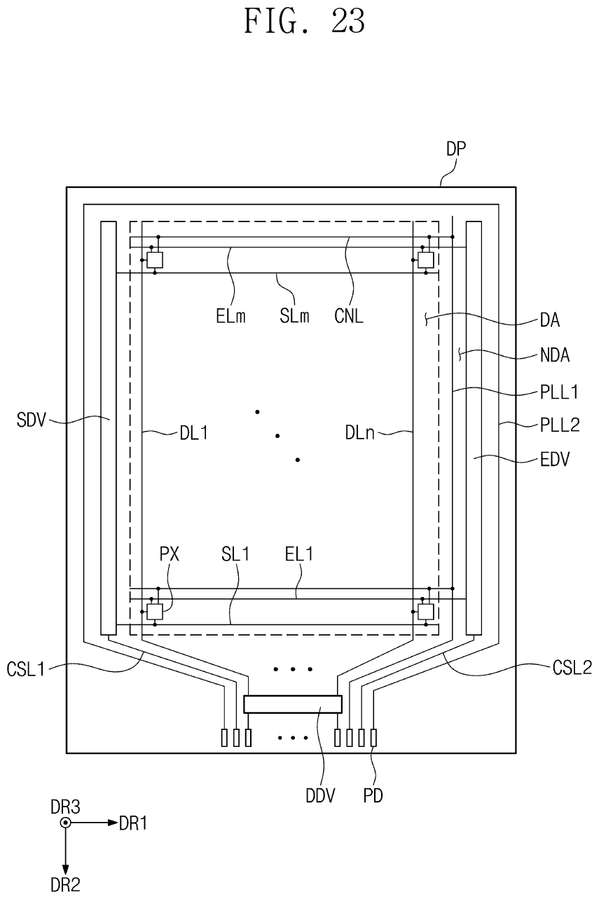

FIG. 23 is a plan view illustrating the display panel manufactured using the mask assembly shown in FIG. 5.

Referring to FIG. 23, the display panel DP may have a rectangular shape defined by short sides extending in the first direction DR1 and long sides extending in the second direction DR2, however, the shape of the display panel DP should not be limited thereto. The display panel DP may include a display area DA and a non-display area NDA surrounding the display area DA.

The display panel DP may be a light emitting type display panel. The display panel DP may be an organic light emitting display panel or a quantum dot light emitting display panel. A light emitting layer of the organic light emitting display panel may include an organic light emitting material. A light emitting layer of the quantum dot light emitting display panel may include a quantum dot or a quantum rod. Hereinafter, the organic light emitting display panel will be described as a representative example of the display panel DP.

The display panel DP may include pixels PX, scan lines SL1 to SLm, data lines DL1 to DLn, emission lines EL1 to ELm, first and second control lines CSL1 and CSL2, first and second power lines PLL1 and PLL2, connection lines CNL, and pads PD. Each of “m” and “n” is a natural number.

The pixels PX may be arranged in the display area DA. A scan driver SDV and an emission driver EDV may be disposed in the non-display area NDA respectively adjacent to the long sides of the display panel DP. A data driver DDV may be disposed in the non-display area NDA adjacent to one short side of the short sides of the display panel DP. The data driver DDV in a plan view may be disposed adjacent to a lower end of the display panel DP.

The scan lines SL1 to SLm may extend in the first direction DR1 and may be electrically connected to the pixels PX and the scan driver SDV. The data lines DL1 to DLn may extend in the second direction DR2 and may be electrically connected to the pixels PX and the data driver DDV. The emission lines EL1 to ELm may extend in the first direction DR1 and may be electrically connected to the pixels PX and the emission driver EDV.

The first power line PLL1 may extend in the second direction DR2 and may be disposed in the non-display area NDA. The first power line PLL1 may be disposed between the display area DA and the emission driver EDV, however, it should not be limited thereto. According to an embodiment, the first power line PLL1 may be disposed between the display area DA and the scan driver SDV.

The connection lines CNL may extend in the first direction DR1 and may be arranged in the second direction DR2. The connection lines CNL may be electrically connected to the first power line PLL1 and the pixels PX. A first voltage may be applied to the pixels PX through the first power line PLL1 and the connection lines CNL connected to the first power line PLL1.

The second power line PLL2 may be disposed in the non-display area NDA. The second power line PLL2 may extend along long sides of the display panel DP and another short side at which the data driver DDV is not disposed in the display panel DP. The second power line PLL2 may be disposed outside the scan driver SDV and the emission driver EDV.

Although not shown in figures, the second power line PLL2 may extend to the display area DA and may be electrically connected to the pixels PX. A second voltage having a level lower than that of the first voltage may be applied to the pixels PX through the second power line PLL2.

The first control line CSL1 may be electrically connected to the scan driver SDV and may extend toward the lower end of the display panel DP in a plan view. The second control line CSL2 may be electrically connected to the emission driver EDV and may extend toward the lower end of the display panel DP in a plan view. The data driver DDV may be disposed between the first control line CSL1 and the second control line CSL2.

The pads PD may be disposed on the display panel DP. The pads PD may be disposed closer to the lower end of the display panel DP than the data driver DDV is. The data driver DDV, the first power line PLL1, the second power line PLL2, the first control line CSL1, and the second control line CSL2 may be electrically connected to the pads PD. The data lines DL1 to DLn may be electrically connected to the data driver DDV, and the data driver DDV may be electrically connected to the pads PD corresponding to the data lines DL1 to DLn.

Light emitting elements of the display panel DP may be formed by the cell areas CA shown in FIG. 5. Unit areas corresponding to the display panel DP may be defined in the target substrate M-SUB. In case that the light emitting elements are formed in the unit areas, the unit areas may be cut. As a result, the display panel DP shown in FIG. 23 may be manufactured.

Although not shown in figures, a timing controller to control an operation of the scan driver SDV, the data driver DDV, and the emission driver EDV and a voltage generator to generate the first and second voltages may be disposed on a printed circuit board. The timing controller and the voltage generator may be electrically connected to corresponding pads PD through the printed circuit board.

The scan driver SDV may generate scan signals, and the scan signals may be applied to the pixels PX through the scan lines SL1 to SLm. The data driver DDV may generate data voltages, and the data voltages may be applied to the pixels PX through the data lines DL1 to DLn. The emission driver EDV may generate emission signals, and the emission signals may be applied to the pixels PX through the emission lines EL1 to ELm.

The pixels PX may receive the data voltages in response to the scan signals. The pixels PX may emit a light having a luminance corresponding to the data voltages in response to the emission signals, and thus, an image may be displayed. An emission time of the pixels PX may be controlled by the emission signals.

The lines described above may include the data lines DL1 to DLn. Pads connected to the lines described above may include the pads PD shown in FIG. 23. The display panel DP in which the light emitting layers of the pixels PX are not formed may be defined as the target substrate M-SUB described above.

FIG. 24 is a cross-sectional view illustrating a pixel PX shown in FIG. 23.

The pixel PX may be disposed on a base substrate BL and may include a transistor TR and a light emitting element OLED. The transistors TR and the light emitting elements OLED of the pixels PX may be electrically connected to the data lines DL1 to DLn and the first and second power lines PLL1 and PLL2. The transistors TR and the light emitting elements OLED of the pixels PX may be electrically connected to the pads PD through the data lines DL1 to DLn and the first and second power lines PLL1 and PLL2.

The light emitting element OLED may include a first electrode AE, a second electrode CE, a hole control layer HCL, an electron control layer ECL, and the light emitting layer EML. The first electrode AE may be an anode electrode, and the second electrode CE may be a cathode electrode.

The transistor TR and the light emitting element OLED may be disposed on the base substrate BL. As an example, one transistor TR is shown, however, the pixel PX may include a plurality of transistors and at least one capacitor to drive the light emitting element OLED.

The display area DA may include a light emitting area PA corresponding to the pixel PX and a non-light-emitting area NPA around the light emitting area PA. The light emitting element OLED may be disposed in the light emitting area PA.

The base substrate BL may include a flexible plastic substrate. As an example, the base substrate BL may include transparent polyimide (PI). A buffer layer BFL may be disposed on the base substrate BL, and the buffer layer BFL may be an inorganic layer.

A semiconductor pattern may be disposed on the buffer layer BFL. The semiconductor pattern may include polycrystalline silicon, however, it should not be limited thereto. According to an embodiment, the semiconductor pattern may include amorphous silicon or metal oxide.

The semiconductor pattern may be doped with an N-type dopant or a P-type dopant. The semiconductor pattern may include a high-doped region and a low-doped region. The high-doped region may have a conductivity greater than that of the low-doped region and may substantially serve as a source electrode and a drain electrode of the transistor TR. The low-doped region may substantially correspond to an active (or a channel) of the transistor.

A source S-D, an active A-D, and a drain D-D of the transistor TR may be formed from the semiconductor pattern. A first insulating layer 10 may be disposed on the semiconductor pattern. A gate G-D of the transistor TR may be disposed on the first insulating layer 10. A second insulating layer 20 may be disposed on the gate G-D. A third insulating layer 30 may be disposed on the second insulating layer 20.

A connection electrode CNE may be disposed between the transistor TR and the light emitting element OLED to connect the transistor TR to the light emitting element OLED. The connection electrode CNE may include a first connection electrode CNE1 and a second connection electrode CNE2.

The first connection electrode CNE1 may be disposed on the third insulating layer 30 and may be electrically connected to the drain D-D via a first contact hole CNT-1 defined through the first, second, and third insulating layers 10, 20, and 30. A fourth insulating layer 40 may be disposed on the first connection electrode CNE1. A fifth insulating layer 50 may be disposed on the fourth insulating layer 40.

The second connection electrode CNE2 may be disposed on the fourth insulating layer 40. The second connection electrode CNE2 may be electrically connected to the first connection electrode CNE1 via a second contact hole CNT-2 defined through the fourth insulating layer 40.

The first electrode AE may be disposed on the fifth insulating layer 50. The first electrode AE may be electrically connected to the second connection electrode CNE2 via a third contact hole CNT-3 defined through the sixth insulating layer 60. A pixel definition layer PDL may be disposed on the first electrode AE and the sixth insulating layer 60 to expose a portion of the first electrode AE. An opening PX_OP may be defined through the pixel definition layer PDL to expose the portion of the first electrode AE.

The hole control layer HCL may be disposed on the first electrode AE and the pixel definition layer PDL. The hole control layer HCL may be commonly disposed in the light emitting area PA and the non-light-emitting area NPA. The hole control layer HCL may include a hole transport layer and a hole injection layer.

The light emitting layer EML may be disposed on the hole control layer HCL. The light emitting layer EML may be disposed in an area corresponding to the opening PX_OP. The light emitting layer EML may include an organic material and/or an inorganic material. The light emitting layer EML may generate a light having one of red, green, and blue colors.

The electron control layer ECL may be disposed on the light emitting layer EML and the hole control layer HCL. The electron control layer ECL may be commonly disposed in the light emitting area PA and the non-light-emitting area NPA. The electron control layer ECL may include an electron transport layer and an electron injection layer.

The second electrode CE may be disposed on the electron control layer ECL. The second electrode CE may be commonly disposed over the pixels PX. Layers from the buffer layer BFL to the light emitting element OLED may be referred to as a pixel layer.

A thin film encapsulation layer TFE may be disposed on the light emitting element OLED. The thin film encapsulation layer TFE may be disposed on the second electrode CE to cover the pixel PX. The thin film encapsulation layer TFE may include at least two inorganic layers and an organic layer disposed between the inorganic layers. The inorganic layers may protect the pixel PX from moisture and oxygen. The organic layer may protect the pixel PX from a foreign substance such as dust particles.

The first voltage may be applied to the first electrode AE via the transistor TR, and the second voltage having the level lower than the first voltage may be applied to the second electrode CE. Holes and electrons injected into the light emitting layer EML may be recombined to generate excitons, and the light emitting element OLED may emit the light by the excitons that return to a ground state from an excited state.

FIG. 25 is a view illustrating a deposition process performed by the deposition apparatus shown in FIG. 4.

Referring to FIG. 25, the components from the base substrate BL to the hole control layer HCL may correspond to the target substrate M-SUB shown in FIG. 4.

The mask assembly MA (refer to FIG. 4) may be disposed to face the target substrate M-SUB. However, for the sake of explanation, components except the mask pattern MP included in the mask assembly MA (refer to FIG. 4) are omitted in FIG. 24.

FIG. 25 illustrates a process of forming the light emitting layer EML of the display panel shown in FIG. 24.

For the convenience of explanation, FIG. 25 illustrates a structure in which the target substrate M-SUB (refer to FIG. 4) is positioned at the bottom and the mask pattern MP is positioned at the top in the third direction DR3, however, the arrangement direction of the mask pattern MP and the target substrate M-SUB (refer to FIG. 4) should not be so limited. According to an embodiment, the deposition process may be performed with the target substrate M-SUB (refer to FIG. 4) positioned at the top and the mask pattern MP positioned at the bottom.

The mask assembly MA (refer to FIG. 4) may be disposed closer to the target substrate M-SUB. The deposition material DM may be provided onto the target substrate M-SUB through the deposition openings OP1. The light emitting layer EML may be formed on the target substrate M-SUB by the deposition material DM.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A method of manufacturing a mask assembly, comprising:
providing a wafer;
forming a photoresist layer on the wafer;
placing a photomask above the photoresist layer and irradiating a light to the photoresist layer through the photomask to form photoresist openings penetrating through upper and lower surfaces of the photoresist layer;
forming a mask pattern comprising silicon (Si) in the photoresist openings using a chemical vapor deposition process; and
removing the photoresist layer.

2. The method of claim 1, wherein the wafer comprises silicon (Si), and the mask pattern comprises silicon nitride (SiOₓ) or silicon oxide (SiOₓ).

3. The method of claim 1, wherein an upper surface of the wafer and each of side surfaces of the mask pattern form an angle greater than or equal to about 60° and smaller than or equal to about 70° in a cross-sectional view.

4. The method of claim 1, wherein the lower surfaces of the photoresist layer and each of side surfaces of the photoresist layer define the photoresist openings and form an angle greater than or equal to about 110° and smaller than or equal to about 120° in a cross-sectional view.

5. The method of claim 1, wherein
after the forming of the mask pattern and before the removing of the photoresist layer, each of portions of the mask pattern are spaced apart from each other by at least a portion of the photoresist layer, and
each of the portions of the mask pattern has a width that increases as a distance from the wafer increases in a cross-sectional view.

6. The method of claim 1, wherein
after the forming of the mask pattern and before the removing of the photoresist layer, each of portions of the mask pattern are spaced apart from each other by at least a portion of the photoresist layer,
each of the portions of the mask pattern has an inverted tapered shape in a cross-sectional view.

7. The method of claim 1, wherein
after the forming of the mask pattern and before the removing of the photoresist layer, each of portions of the photoresist layer are spaced apart from each other by a corresponding portion of the mask pattern,
each of the portions of the photoresist layer has a width that decreases as a distance from the wafer increases in a cross-sectional view.

8. The method of claim 1, wherein the photoresist layer comprises a positive photoresist.

9. The method of claim 8, wherein
photo openings are defined through upper and lower surfaces of the photomask, and
the photoresist openings formed through the photoresist layer correspond to the photo openings.

10. The method of claim 1, wherein the removing of the photoresist layer comprises wet-etching the photoresist layer or ashing the photoresist layer.

11. The method of claim 1, wherein
areas where portions of the photoresist layer are arranged in the mask pattern are defined as pattern areas, and
the chemical vapor deposition process is performed at a temperature of about 60° C. or greater and about 100° C. or less.

12. The method of claim 11, further comprising etching the wafer from a lower surface of the wafer to an upper surface of the wafer to form a cell opening completely penetrating through the lower and upper surfaces of the wafer after the removing of the photoresist layer.

13. A method of manufacturing a mask assembly, comprising:
providing a wafer;
forming a photoresist layer on the wafer;
forming photoresist openings through the photoresist layer and that penetrate through upper and lower surfaces of the photoresist layer and that have an inverted tapered shape in a cross-sectional view;
forming a mask pattern based on at least partially filling the photoresist openings; and
removing the photoresist layer.

14. The method of claim 13, wherein the wafer comprises silicon (Si), and the mask pattern comprises silicon nitride (SiOₓ) or silicon oxide (SiOₓ).

15. The method of claim 13, wherein an upper surface of the wafer and each of side surfaces of the mask pattern form an angle greater than or equal to about 60° and smaller than or equal to about 70° in a cross-sectional view.

16. The method of claim 13, wherein
after the forming of the mask pattern and before the removing of the photoresist layer, each of portions of the mask pattern are spaced apart from each other by at least a portion of the photoresist layer, and
each of the portions of the mask pattern has a width that increases as a distance from the wafer increases in a cross-sectional view.

17. The method of claim 13, wherein the forming of the photoresist openings comprises:
placing a photomask comprising photo openings defining the photoresist openings; and
irradiating a light to the photoresist layer through the photomask, the photoresist layer comprising a positive photoresist.

18. The method of claim 13, wherein, after the forming of the mask pattern and before the removing of the photoresist layer, the photoresist layer and the mask pattern are directly in contact with an upper surface of the wafer.

19. The method of claim 13, wherein the removing of the photoresist layer comprises wet-etching the photoresist layer or ashing the photoresist layer.

20. The method of claim 13, further comprising etching the wafer from a lower surface of the wafer to an upper surface of the wafer to form a cell opening, wherein
areas where portions of the photoresist layer are arranged in the mask pattern are defined as pattern areas,
deposition openings overlapping the pattern areas and penetrating through upper and lower surfaces of the mask pattern are formed using the mask pattern based on the removing of the photoresist layer, and
the cell opening overlaps the deposition openings.

21. An electronic device comprising a display panel manufactured using the method of claim 1.
